(19) United States
(12) Patent Application Publication
(10) Pub. No.: US 2005/0179056 A1
(43) Pub. Date: Aug. 18, 2005

(54) System for resonant circuit tuning

(76) Inventors: Ross E. Teggatz, McKinney, TX (US); David J. Baldwin, Allen, TX (US)

Correspondence Address: TEXAS INSTRUMENTS INCORPORATED, P O BOX 655474, M/S 3999, DALLAS, TX, 75265, US

(21) Appl. No.: 10/781,559

(22) Filed: Feb. 18, 2004

(51) Int. Cl. G11C 5/00

(52) U.S. Cl. 257/200

(57) ABSTRACT

The present invention provides a system for producing a tunable resonant circuit (200), where the resonant circuit utilizes both integrated semiconductor devices and discrete components. The system provides a driver circuit (208) instantiated within a first integrated semiconductor device (210), an inductive load (204), and a resistive element (202) intercoupled therebetween. One terminal of the inductive load is coupled to a first terminal of a reduction system (214). A second terminal of the reduction system is coupled to a node (216). A primary capacitive element (206) has a first terminal coupled to a node, and a secondary capacitive element (222) has a first terminal coupled to the node. A switchable element (224) has a first terminal coupled to a second terminal of the secondary capacitive element, and a second terminal coupled to ground. The reduction system is adapted to reduce to operational voltage at the node to a target value.

### TECHNICAL FIELD OF THE INVENTION

The present invention relates generally to the field of electronic systems and components and, more particularly, to apparatus and methods for tuning resonant circuitry utilizing semiconductor devices.

### BACKGROUND OF THE INVENTION

The continual demand for enhanced performance in electronic products and systems has resulted in, among other things, continual efforts to optimize the operational efficiency of components and substructures wherever possible. Dramatic reductions in semiconductor device geometries, integration of board level functions within semiconductor devices, and substantial reductions in system operating voltages are among a wide variety of such efforts that have been undertaken.

At the same time, the use of electronic products and systems has spread into a number of new and distinct applications that, until recently, were not associated with electronic technology. Often, such new applications place a number of unique demands on components and substructures. Consider, for example, the radiation tolerance required of satellite or spacecraft systems, or the heat and shock tolerance required of automotive systems.

Thus, optimized performance over a broader range of operating conditions is required of many electronic components and substructures. This has resulted in a number of improvements and innovations in electronic systems, and has increased the importance of, and attention to, component and substructure properties and behaviors.

Among the innovations so developed, wireless communication technologies have become increasingly popular and widespread. In addition to well-known consumer-oriented wireless applications (e.g., cell phones, wireless PDAs) that commonly employ active wireless transmission and reception systems, there are an increasing number of indirect applications that employ passive wireless transmission and reception systems in a manner transparent to a user or consumer. Such passive wireless systems typically consist of remote transceivers that function only when within the active transmission range of centrally located base transceivers. These passive systems may be designed to operate over a wide variety of distances, and at a variety of frequencies. Examples of such systems include radio frequency identification systems (e.g., windshield-mounted tollway tags) and low frequency transmission systems (e.g., automotive monitoring and diagnostic systems).

Commonly, these wireless transceivers—especially the base transceivers—rely on resonant circuitry to provide a communications signal at a predefined frequency (i.e., a resonant point). Operation of the resonant circuitry is optimized at the resonant point. Operation at a point skewed, even slightly, from the resonant point can significantly impact the reliability of the system, and perhaps even render it inoperable. Due to manufacturing variations in the devices and components utilized in a resonant circuit, such off-resonant operation frequently results. In response, resonant circuits commonly incorporate some form of tuning circuitry. Tuning circuitry provides, after manufacturing, a means to reset a resonant circuit at, or satisfactorily close to, the resonant point.

In certain applications (e.g., automotive monitoring and diagnostic system), however, the system's operational parameters (e.g., voltage, frequency) can result in relatively extreme conditions for tuning circuitry. For example, depending upon the design, operational voltages for certain tuning components (e.g., capacitors, transistors) may be greater than 100 Volts. Conventional tuning systems often rely on a number of individual, discrete components implemented at board level, in addition to certain semiconductor devices. This results in a number of costs and inefficiencies in the overall system design (e.g., larger board space, more discrete signal traces and connections). Integration of discrete components or functions into semiconductor devices appears to have previously been considered commercially unviable—since most high-volume, low-cost semiconductor processes are not able to accommodate such extreme operational levels.

As a result, there is a need for a resonant circuit tuning system that accurately and efficiently tunes a resonant circuit to a desired resonant point, while providing reliable system performance in a cost-effective manner.

### SUMMARY OF THE INVENTION

The present invention provides a versatile system of methods and structures that accurately tune a resonant circuit and enable integration of most, if not all, tuning components into commercially viable semiconductor processes—optimizing design efficiency and system performance in an easy and cost-effective manner, while overcoming limitations associated with other approaches.

Specifically, the present invention provides a reduction system that significantly reduces parametric loading levels for tuning components within resonant circuitry. Operational parameter levels for the tuning components are reduced to a level that facilitates integration of those components into collateral semiconductor devices. As a result, board space is conserved, costs are reduced, and system reliability is increased.

More specifically, one embodiment of the present invention provides a resonant circuit structure that comprises a load. A primary component is coupled to a node, and a secondary component array is also coupled to the node, in parallel to the primary component. A reduction system is intercoupled between the load and the node, and adapted to reduce to operational voltage at the node to a target value.

Another embodiment of the present invention provides a circuitry segment that implements an RLC resonant circuit structure, utilizing integrated and discrete devices. The segment has a driver circuit, instantiated within a first integrated semiconductor device. A primary resistive element has a first terminal coupled the driver circuit, and a second terminal coupled to a first terminal of an inductive load. A reduction system has a first terminal coupled to a second terminal of the inductive load, and a second terminal coupled to a node. A primary capacitive element has a first terminal coupled to the node, and a secondary component array is coupled to the node, in parallel to the primary capacitive element. The reduction system is adapted to reduce to operational voltage at the node to a target value.

The present invention further provides a method of producing a tunable resonant circuit that utilizes both integrated and discrete devices. A driver circuit is instantiated within a first integrated semiconductor device. A primary resistor, having a first terminal coupled the driver circuit, and a second terminal coupled to a first terminal of an inductive load is provided. A primary capacitor is provided, having a first terminal coupled to a node. A secondary capacitor, having a first terminal coupled to the node, is also provided. A transistor is provided, having a first terminal coupled to a second terminal of the secondary capacitor, and a second terminal coupled to ground. The method also provides a reduction system, having one or more intercoupled capacitors, a first terminal of which is coupled to a second terminal of the inductive load, and a second terminal of which coupled to the node, that is adapted to reduce to operational voltage at the node to a target value.

Other features and advantages of the present invention will be apparent to those of ordinary skill in the art upon reference to the following detailed description taken in conjunction with the accompanying drawings.

### BRIEF DESCRIPTION OF THE DRAWINGS

For a better understanding of the invention, and to show by way of example how the same may be carried into effect, reference is now made to the detailed description of the invention along with the accompanying figures in which corresponding numerals in the different figures refer to corresponding parts and in which:

FIG. 1 is an illustration of one embodiment of a resonant circuit without benefit of the present invention;

FIG. 2 is an illustration depicting one embodiment of a resonant circuit according to the present invention;

FIG. 3 is an illustration depicting another embodiment of a resonant circuit according to the present invention; and

FIG. 4 is an illustration depicting another embodiment of a resonant circuit according to the present invention.

### DETAILED DESCRIPTION OF THE INVENTION

While the making and using of various embodiments of the present invention are discussed in detail below, it should be appreciated that the present invention provides many applicable inventive concepts, which can be embodied in a wide variety of specific contexts. The invention will now be described in conjunction with a resonant circuit for a low frequency transmission system. The specific embodiments discussed herein are, however, merely illustrative of specific ways to make and use the invention and do not limit the scope of the invention.

The system of the present invention provides a versatile reduction system, comprising various methods and structures, providing resonant circuit tuning of optimum efficiency and performance by reducing parametric loading on individual tuning and system components. Highly accurate tuning of a resonant circuit is provided, while operational parameter levels for tuning componentry are reduced to a level that facilitates integration of those components or devices into collateral semiconductor devices. Such integration of most, if not all, tuning componentry into commercially viable semiconductor processes optimizes design efficiency and system performance—conserving board space, reducing costs, and increasing system reliability.

A number of modern resonant circuits utilize an RLC (resistance, inductance, capacitance) topology. Although the principles and teachings of the present invention comprehend a wide array of resonant circuit topologies and requirements, the present invention is now described in reference to an RLC topology application (i.e., a resonant circuit in a base transceiver for a low-frequency wireless communication system), for purposes of explanation and illustration.

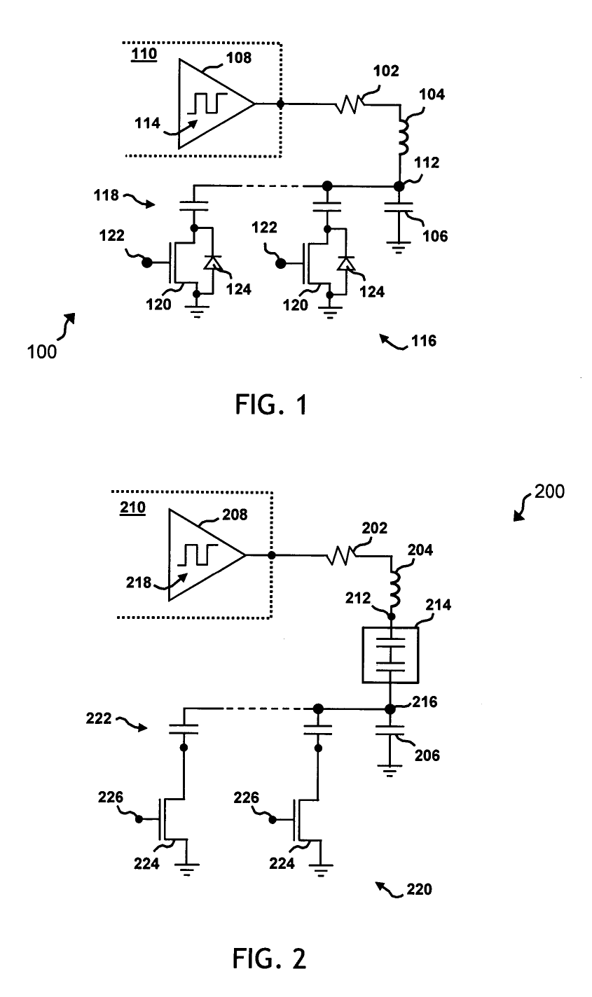

Without the aid of the present invention, a system utilizing an RLC resonant circuit may face a number of issues and complications. Some such concerns are illustrated now in reference to FIG. 1, which depicts a circuitry segment 100 within a wireless base transceiver. Segment 100 comprises an RLC topology having a primary resistor 102, a primary inductive load 104, and a primary capacitor 106. A first terminal of resistor 102 is coupled to a driver circuit 108, which is instantiated within an integrated semiconductor device 110. A second terminal of resistor 102 is coupled to a first terminal of load 104. Inductive load 104, in this application, typically comprises an antenna for receiving or transmitting wireless signals to or from the base transceiver. A second terminal of load 104 is coupled to a node 112. A first terminal of capacitor 106 is coupled to node 112, while a second terminal of capacitor 106 is coupled to ground. Driver 108, through its coupling to resistor 102, delivers a drive signal 114 to segment 100.

The parametric values of components 102, 104 and 106, as well as the characteristics of signal 114 (e.g., frequency, function), are selected to provide a resonant signal of a desired frequency (e.g., 100 kHz, 125 kHz, 150 kHz). Thus, segment 100 and the base transceiver operate at optimum power and efficiency only when segment 100 is resonant at the desired resonant frequency. However, manufacturing tolerances and variances in the various components of segment 100, particularly in antenna 104, can cause segment 100 to operate at a frequency different from the desired resonant frequency. In such an instance, segment 100 operates off-resonance; reducing the signal-strength properties of the base transceiver. This has a significant negative impact on system performance and reliability.

In order to address this, a number of systems implement an array of selectable secondary components in parallel to one of the primary components. Often, this takes the form of a capacitive array 116 provided in parallel with capacitor 106. Array 116, which is coupled to node 112, comprises one or more secondary capacitors 118 that may be selectively activated to alter effective capacitance at node 112. Usually, capacitors 118 are made selectable by coupling each such capacitor between ground, through some readily switchable element 120, and node 112. As depicted in FIG. 1, element 120 comprises a transistor having a first terminal coupled to capacitor 118, a second terminal coupled to ground, and a third terminal coupled to some select control signal node 122. Via node 122, each desired capacitor 118 is activated to alter effective capacitance at node 112. Thus, segment 100 may compensate for variations in component values, and—depending upon the number and value(s) of elements in array 116—may be shifted to operate at or very close to the desired resonant frequency.

Operating voltages for systems utilizing a resonant circuit can vary widely. Many common system applications (e.g., automotive, industrial) operate at relatively high voltages (e.g., 20V, 30V, 60V). Thus, in the example illustrated in FIG. 1, segment 100 may be driven by a signal on the order of 30 or more Volts. Depending upon the desired resonant frequency and the specific component values selected, the resulting resonant voltage at node 112 (V_{RES}) can be significantly higher than the drive voltage—even higher by an order of magnitude or more. As a result, capacitors 106 and 118 and elements 120 must be rated for extremely high operating voltages. Since most low-cost semiconductor devices and processes are not capable of such operation, system designers are often left with no choice but to rely on individual, discrete components, implemented at board level, for capacitors 106 and 118 and elements 120. Such discrete elements are often large—consuming more board space and requiring extra board overhead—and relatively costly. Moreover, where discrete elements 120 are transistors, diodes 124 between the first and second terminals of the transistor—typically inherent in most MOSFET technologies—rectify switching current for an associated secondary capacitor 118. This, in addition to other capacitive coupling effects, results in a voltage swing across transistor 120 that is 2(V_{RES}). In an instance where V_{RES} is ˜300V, the peak voltage capacity between the first and second terminals of transistor 120 must be ˜600V or more. These circumstances nearly, if not completely, eliminate the possibility of integrating any of the secondary array elements into a low-cost semiconductor device. The use of discrete components is necessitated, raising costs and reliability concerns.

In contrast, certain aspects of the present invention are illustrated now in reference to FIG. 2, which depicts a resonant circuitry segment 200 within a wireless base transceiver. With certain distinguishing exceptions, as described hereinafter, segment 200 has structure, topology and function similar to that of segment 100. Segment 200 comprises an RLC topology having a primary resistive element 202, a primary inductive load 204, and a primary capacitive element 206. A first terminal of element 202 is coupled to a driver circuit 208, which is instantiated within an integrated semiconductor device 210. A second terminal of element 202 is coupled to a first terminal of load 204. Inductive load 204 comprises a communication element for receiving or transmitting wireless signals to or from the base transceiver; typically in the form of an antenna. A second terminal of load 204 is coupled to a node 212. A reduction system 214 is intercoupled between node 212 and node 216. A first terminal of element 206 is coupled to node 216, while a second terminal of element 206 is coupled to ground. Driver 208, through its coupling to element 202, delivers a drive signal 218 to segment 200.

The resistance, inductance, and capacitance values, as well as the characteristics of signal 218 (e.g., frequency, function), are determined or selected for providing a resonant signal of a desired frequency (e.g., 100 kHz, 125 kHz, 150 kHz). In segment 200, element 202 provides a required resistance. Although depicted as a single resistor in FIG. 2, element 202 may—in alternative embodiments—comprise one or more resistive elements (e.g., resistors, transistors) coupled in series. In other alternative embodiments, element 202 may be omitted completely—such embodiments relying instead on resistance values inherent in other components along a signal path. The inductive value of load 204 is generally fixed; being produced for some target value within certain tolerances, depending upon the nature of the load component (e.g., antenna). Element 206 is depicted as a single capacitor in FIG. 2. In alternative embodiments, element 206 may comprise one or more components or devices, capacitors or otherwise, coupled serially, in parallel, or in some combined network, that function in accordance with the present invention.

In segment 200, capacitance relied upon in providing a desired resonant frequency is the capacitance as measured between node 212 and ground. The necessary capacitance is thus cumulatively provided by reduction system 214 in series with the parallel combination of primary capacitor 206 and a secondary component array 220. In this embodiment, array 220 is provided as a parallel capacitive array, coupled to node 216. Array 220 comprises one or more secondary capacitors 222 that may be selectively activated to alter effective capacitance at node 212. Each such capacitor 222 is coupled between node 216 and a switchable element 224. As depicted in FIG. 2, element 224 comprises a transistor having a first terminal coupled to capacitor 222, a second terminal coupled to ground, and a third terminal coupled to some select control signal node 226. In alternative embodiments, element 224 may comprise any other suitable element, circuit or component that provides selective activation of a capacitor 222. A control signal is asserted, via node 226, to activate or deactivate a specific capacitor 222—altering the effective capacitance at node 212 to tune segment 200 to a desired resonant frequency. As such, segment 200 provides compensation for variations in fixed component values.

According to the present invention, reduction system 214 is disposed between load is 204 and capacitor 206. In this embodiment, system 214 is provided to form a capacitive divider network with the combination of capacitor 206 and array 220. System 214 is provided with a capacitive value sufficient to reduce the operational (i.e. resonant) voltage V_{RES}, as measured at node 216, to or below some target value. This target voltage is set sufficiently low enough to enable integration of some or all componentry within array 220 into a commercially viable semiconductor process. For example, if V_{RES} at node 212 is 300V, then system 214, capacitor 206 and system 220 may be designed or selected such that V_{RES} at node 216 is 30V or less. Thus, the capacitive value of system 214 is relatively large in comparison to capacitor 206—anywhere from several times as large to orders of magnitude larger than capacitor 206.

As depicted in FIG. 2, system 214 comprises a plurality of capacitors coupled in series. In alternative embodiments, a single large capacitor may be used. In still other embodiments, combinations of serially and parallel coupled capacitors may be used. The number and relative size of the capacitors may be varied, depending upon the constraints and requirements of a particular system design (e.g., voltages, frequency).

For the configuration depicted in FIG. 2, using a larger number of smaller capacitors reduces the voltage across each and, correspondingly, reduces high voltage capacitance drift. Additionally, if system 214 is implemented using discrete components or devices, it is possible that several small capacitors may cost less than a single large capacitor. In contrast, using a smaller number of larger capacitors may reduce the board or silicon space consumed by system 214. Larger capacitors, however, are more susceptible to high voltage capacitance drift—which might result in tuning problems. These and other similar tradeoffs may be made to optimize cost, performance and efficiency of the system. Thus, according to the present invention, the number and configuration of components implementing system 214 may be varied according to specific design requirements or conditions.

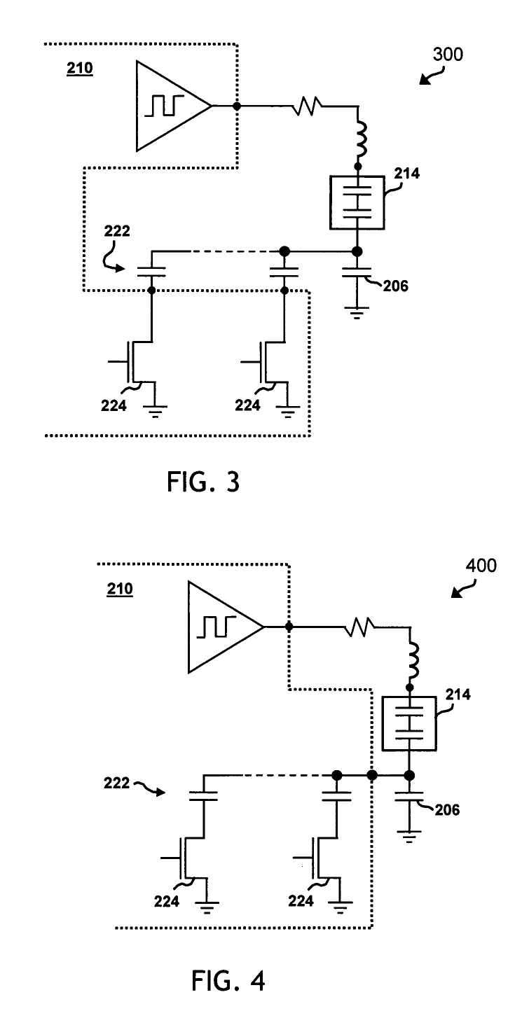

By reducing V_{RES} at node 216 to an operational level within the capabilities of a commercially viable semiconductor process, the present invention provides for the partial or complete integration of components within system 220 into such a semiconductor process. For example, the element(s) 224 of system 220 may be integrated into a semiconductor device. This is illustrated in FIG. 3, which depicts one alternative embodiment 300 of the present invention in which transistors 224 are integrated into semiconductor device 210. In other alternative embodiments, all transistors 224 may be integrated into a semiconductor device independent of device 210. In still another alternative embodiment, each transistor 224 may be integrated into a separate semiconductor device—each independent of device 210. Other variations and combinations thereof in accordance with the present invention are further comprehended thereby.

Such integrations of the transistor(s) provide a tremendous benefit to overall system cost and performance. Even where certain embodiments of system 214 rely on the addition of several moderate-value, board-mounted, discrete capacitors to the system board, a net improvement in board layout space, system performance and, especially, cost is generally realized. Most discrete transistors suitable for such performance levels are, relatively speaking, very expensive—even in extremely high volume quantities. Furthermore, the signal routing associated with discrete transistors, and the transistors themselves, typically consume more board space than a comparable number of small to medium size discrete capacitors.

In other alternative embodiments of the present invention, some or all of the capacitors within segment 200 may be integrated into a semiconductor device. In making the decision of whether to implement the present invention using board-mounted discrete capacitors or semiconductor capacitors, certain tradeoffs might be made depending upon system characteristics, requirements and constraints. Depending upon the semiconductor processes available and the required values of capacitors 222, 206 or 214, full or partial integration may not even be possible. Some semiconductor processes are incapable of forming capacitors of sufficient strength or size for such applications. Nonetheless, a substantial improvement in design efficiency and performance is still realized through semiconductor integration of transistors 224, as previously described.

In other instances, the available semiconductor processes may be capable of forming the required capacitors but, in doing so, a substantial amount of semiconductor layout space is consumed. As such, from an overall system perspective (e.g., cost, performance, form factor), use of discrete components for some or all the required capacitors may be more efficient. Again, a substantial benefit to system efficiency and performance is still realized through implementing other aspects of the present invention.

In instances where available semiconductor processes are capable of forming the required capacitors in an efficient manner, integration of all capacitors may be provided—unless doing so would violate some other system requirement (e.g., physical location constraints).

One illustrative embodiment of capacitor integration according to the present invention is depicted in FIG. 4. In FIG. 4, one embodiment 400 of the present invention has capacitors 222, in addition to transistors 224, integrated into semiconductor device 210. Only capacitor 206 and system 214 utilize discrete components. As with transistors 224, the integrated capacitors 222 may be combined with transistors 224—all within device 210. Alternatively, each capacitor may be provided in a separate semiconductor device, or varying combinations of capacitors and transistors across a number of semiconductor devices may be provided. All such variations and combinations are comprehended by the present invention.

The present invention further provides another significant benefit to overall system performance and stability. As previously described, the system of the present invention significantly reduces the voltage loading on capacitor 206 and system 220. In order to realize a necessary resonance capacitance at node 212, the parametric capacitance values of components within elements 214, 206 and 220 may be larger than corresponding discrete capacitors in conventional approaches. Due, however, to the lower voltage across capacitive components within elements 214, 206 and 220, those elements may have an actual physical size that is smaller than corresponding discrete capacitors—operating at higher voltages—in conventional approaches. For example, a system having segment 100 may require a capacitor 106 on the order of 100 pF. In comparison, a system having segment 200 may require a capacitor 206 on the order of 10 nF. The physical size of capacitor 206 may, however, be equal to or significantly less than the physical size of the discrete capacitor 106. Smaller capacitor sizes provide for embodiments that incorporate a greater number of capacitive elements in segment 200—providing a finer resolution in tuning segment 200 to its target resonant frequency. This results in a more accurate, efficient and reliable system.

The present invention thus provides resonant circuit tuning with optimum efficiency and performance at a desired resonant frequency, by reducing parametric loading on individual tuning and system components. Utilizing the principles and teachings of the present invention, a number of resonant circuit topologies may be optimized from a performance and cost efficiency perspective. A number of embodiments, variations and combinations of the present are comprehended hereby. For example, although the present invention has been explained and illustrated in reference to a series resonant circuit, the system of the present invention may, depending upon the specific application, be similarly applied to other resonant circuit configurations, such as a parallel resonant circuit. In such an application, the capacitive network and elements are coupled in parallel to an inductive load, as opposed to being coupled serially. The present invention nonetheless provides benefits and advantages similar to those described herein in relation to a serial configuration. Furthermore, although the present invention has been explained and illustrated in the context of a low frequency resonant circuit, the system of the present invention may be similarly applied to resonant circuits of varying frequencies (e.g., radio frequency). Any and all such applications and variations of the present invention are comprehended hereby.

Therefore, the embodiments and examples set forth herein are therefore presented to best explain the present invention and its practical application, and to thereby enable those skilled in the art to make and utilize the invention. However, those skilled in the art will recognize that the foregoing description and examples have been presented for the purpose of illustration and example only. The description as set forth is not intended to be exhaustive or to limit the invention to the precise form disclosed. As indicated, a number of modifications and variations are possible in light of the above teaching without departing from the spirit and scope of the following claims.

1. A resonant circuit structure comprising:
a load;
a primary component coupled to a node;
a secondary component array coupled to the node, in parallel to the primary component; and
a reduction system, intercoupled between the load and the node, and adapted to reduce to operational voltage at the node to a target value.

2. The structure of claim 1, wherein the resonant circuit structure comprises an inductive load and a capacitance coupled in series.

3. The structure of claim 1, wherein the load comprises an antenna.

4. The structure of claim 1, wherein the primary component comprises a capacitive element.

5. The structure of claim 4, wherein the capacitive element is a capacitor.

6. The structure of claim 4, wherein the secondary component array comprises a capacitive element.

7. The structure of claim 6, wherein the capacitive element is a capacitor.

8. The structure of claim 6, wherein the secondary component array comprises a switchable element.

9. The structure of claim 8, wherein the switchable element is a transistor.

10. A circuitry segment, implementing an RLC resonant circuit structure utilizing integrated and discrete devices, the circuitry segment comprising:
a driver circuit, instantiated within a first integrated semiconductor device;
a primary resistive element, having a first terminal coupled the driver circuit, and a second terminal coupled to a first terminal of an inductive load;
a reduction system, having a first terminal coupled to a second terminal of the inductive load, and having a second terminal coupled to a node;
a primary capacitive element, having a first terminal coupled to the node; and
a secondary component array coupled to the node, in parallel to the primary capacitive element;
wherein the reduction system is adapted to reduce to operational voltage at the node to a target value.

11. The circuitry segment of claim 10, wherein the RLC resonant circuit structure is a low frequency resonant circuit.

12. The circuitry segment of claim 10, wherein the RLC resonant circuit structure is a radio frequency resonant circuit.

13. The circuitry segment of claim 10, wherein the primary resistive element is a resistor.

14. The circuitry segment of claim 13, wherein the resistor is a discrete component.

15. The circuitry segment of claim 10, wherein the inductive load is an antenna.

16. The circuitry segment of claim 15, wherein the antenna is for a base transceiver in a wireless communication system.

17. The circuitry segment of claim 10, wherein the primary capacitive element comprises a capacitor.

18. The circuitry segment of claim 10, wherein the primary capacitive element comprises a plurality of capacitors.

19. The circuitry segment of claim 17, wherein the capacitor is a discrete component.

20. The circuitry segment of claim 17, wherein the capacitor is integrated within a semiconductor device.

21. The circuitry segment of claim 10, wherein the secondary component array comprises a capacitor.

22. The circuitry segment of claim 10, wherein the secondary component array comprises a switchable element.

23. The circuitry segment of claim 22, wherein the switchable element comprises a transistor.

24. The circuitry segment of claim 21, wherein the capacitor is a discrete component.

25. The circuitry segment of claim 21, wherein the capacitor is integrated within a semiconductor device.

26. The circuitry segment of claim 23, wherein the transistor is integrated within a semiconductor device.

27. The circuitry segment of claim 10, wherein the reduction system comprises a capacitor.

28. The circuitry segment of claim 10, wherein the reduction system comprises a plurality of capacitors.

29. The circuitry segment of claim 27, wherein the capacitor is a discrete component.

30. The circuitry segment of claim 27, wherein the capacitor is integrated within a semiconductor device.

31. A method of producing a tunable resonant circuit, having integrated and discrete devices, the method comprising the steps of:
providing a driver circuit instantiated within a first integrated semiconductor device;
providing a primary resistor, having a first terminal coupled the driver circuit, and a second terminal coupled to a first terminal of an inductive load;
providing a primary capacitor, having a first terminal coupled to a node;
providing a secondary capacitor having a first terminal coupled to the node;
providing a transistor having a first terminal coupled to a second terminal of the secondary capacitor, and a second terminal coupled to ground; and
providing a reduction system, having one or more intercoupled capacitors, a first terminal of which is coupled to a second terminal of the inductive load, and a second terminal of which coupled to the node, adapted to reduce to operational voltage at the node to a target value.

32. The method of claim 31, wherein the step of providing a transistor further comprises providing a transistor instantiated within an integrated semiconductor device.

33. The method of claim 32, wherein the step of providing a transistor further comprises providing a transistor instantiated within the first integrated semiconductor device.

34. The method of claim 31, wherein the step of providing a secondary capacitor further comprises providing a secondary capacitor instantiated within an integrated semiconductor device.

35. The method of claim 34, wherein the step of providing a secondary capacitor further comprises providing a secondary capacitor instantiated within the first integrated semiconductor device.
